(19) United States
(12) Patent Application Publication
(10) Pub. No.: US 2026/0344492 A1
(43) Pub. Date: Oct. 29, 2026

(54) Semiconductor Package Inspection Apparatus and Method of Manufacturing Semiconductor Package Using the Same

(71) Applicant: Samsung Electronics Co., Ltd., Suwon-si (KR)

(72) Inventors: Wongil Han, Suwon-si (KR); Byongjoo Kim, Suwon-si (KR); Heonuk Lim, Suwon-si (KR); Doojin Kim, Suwon-si (KR); Youehwang Yoon, Suwon-si (KR); Jongho Lee, Suwon-si (KR)

(21) Appl. No.: 19/387,171

(22) Filed: Nov. 12, 2025

(30) Foreign Application Priority Data
Apr. 23, 2025 (KR) 10-2025-0053204

(51) Int. Cl. H10W 72/00

(52) U.S. Cl. CPC H10W 72/075; H10W 72/0711; H10W 72/07183; H10W 72/07531

(57) ABSTRACT

A semiconductor package inspection apparatus includes a voltage detector configured to output a detected voltage by measuring a voltage of a wire electrically connected to a bonding pad of at least one semiconductor chip mounted on a package substrate and a bonding controller controlling the voltage detector. The voltage detector includes a voltage source applying a DC voltage to the wire, the variable resistor connected between the wire and the voltage source, and a voltmeter measuring a voltage of the variable resistor. The bonding controller adjusts a resistance value of the variable resistor and a level of the DC voltage, measures a wire current flowing through the wire based on the resistance value of the variable resistor and the level of the detected voltage, and detects a short-circuit defect based on the wire current.

### CROSS-REFERENCE TO RELATED APPLICATION(S)

This application claims the benefit of an earlier filing date and right of priority under 35 U.S.C. §119 to Korean Patent Application No. 10-2025-0053204 filed on April 23, 2025 in the Korean Intellectual Property Office, the disclosure of which is incorporated herein by reference in its entirety.

### TECHNICAL FIELD

The present disclosure relates to a semiconductor package inspection apparatus and a method of manufacturing a semiconductor package using the same.

### BACKGROUND

A semiconductor packaging process may include a wire bonding process for electrically connecting a package substrate to a semiconductor chip and a test process for detecting defects in a semiconductor package. In the wire bonding process, non-contact inspection may be performed simultaneously during wire bonding, thereby detecting open wire defects even before the test process and improving the efficiency of the semiconductor packaging process. However, it may be difficult to detect types of defects other than the open wire defects with the existing non-contact inspection that may be performed during the wire bonding process.

### SUMMARY

According to an aspect of the present disclosure, a semiconductor package inspection apparatus includes: a voltage detector outputting a detected voltage by measuring a voltage of a wire electrically connected to a bonding pad of at least one semiconductor chip mounted on a package substrate; and a bonding controller controlling the voltage detector, wherein the voltage detector includes: a voltage source applying a DC voltage to the wire; the variable resistor connected between the wire and the voltage source; and a voltmeter measuring a voltage of the variable resistor, and wherein the bonding controller adjusts a resistance value of the variable resistor and a level of the DC voltage, measures a wire current flowing through the wire based on the resistance value of the variable resistor and the level of the detected voltage, and detects a short-circuit defect based on the wire current.

According to an aspect of the present disclosure, a method of manufacturing a semiconductor package includes: bonding an end of a wire passing through a capillary to a bonding pad of at least one semiconductor chip mounted on a package substrate; moving the capillary to a connection pad of the package substrate corresponding to the bonding pad; adjusting, when moving the capillary to the connection pad, a magnitude of a variable resistor electrically connected to the wire to a first resistance value, adjusting a level of a DC voltage applied to the wire to a first level, and measuring a voltage of the wire to output a first detected voltage; measuring a wire current flowing in the wire based on the first resistance value and a level of the first detected voltage; detecting a short-circuit defect of the at least one semiconductor chip based on the wire current; and bonding the wire to the connection pad to connect the bonding pad to the connection pad.

According to an aspect of the present disclosure, a method of manufacturing a semiconductor package includes: bonding an end of a wire passing through a capillary to a bonding pad of at least one semiconductor chip mounted on a package substrate; moving the capillary to a connection pad of the package substrate corresponding to the bonding pad; measuring a wire current flowing in the wire; bonding the wire to the connection pad to connect the bonding pad to the connection pad; determining a signal corresponding to the wire current to be an abnormal signal when a magnitude of the wire current is greater than a reference current and determining a signal corresponding to the wire current to be a normal signal when the magnitude of the wire current is smaller than the reference current; collecting the signal corresponding to the wire current as data; and determining that the short-circuit defect has occurred in a process other than a wire bonding process when the data includes only the abnormal signal, determining that the short-circuit defect has occurred during the wire bonding process when the data includes both the normal signal and the abnormal signal and the ratio of the abnormal signal is higher than a reference ratio, and determining that the short-circuit defect has not occurred when the ratio of the abnormal signal in the data is lower than the reference ratio.

### BRIEF DESCRIPTION OF DRAWINGS

These and other aspects, features, and advantages of the present disclosure will be more clearly understood from the following detailed description, taken in conjunction with the accompanying drawings.

FIG. 1 is a block diagram illustrating a wire bonding device according to some implementations of the present disclosure.

FIG. 2 is a flowchart illustrating a method of manufacturing a semiconductor package according to some implementations of the present disclosure.

FIG. 3 is a flowchart illustrating a method of detecting a defect in a wire by a semiconductor package inspection apparatus according to some implementations of the present disclosure.

FIGS. 4 to 11 are diagrams illustrating a semiconductor package according to some implementations of the present disclosure.

FIGS. 12 to 15 are diagrams illustrating a semiconductor package according to some implementations of the present disclosure.

FIGS. 16A and 16B are graphs illustrating a detected voltage measured by a semiconductor package inspection apparatus according to some implementations of the present disclosure.

FIGS. 17A and 17B and FIGS. 18A, 18B, and 18C are graphs illustrating wire current measured by a semiconductor package inspection apparatus according to some implementations of the present disclosure.

### DETAILED DESCRIPTION

An aspect of the present disclosure is to provide a semiconductor package inspection apparatus and a method of manufacturing a semiconductor package, capable of measuring wire current flowing in a wire connected to a bonding pad and detecting various defects that may occur during or before a wire bonding process in addition to open wire defects based on wire current.

However, the problem to be solved by the present disclosure is not limited to the problems mentioned above and may be variously expanded within the scope thereof without departing from the spirit and scope of the present disclosure.

Hereinafter, implementations of the present disclosure will be described with reference to the accompanying drawings.

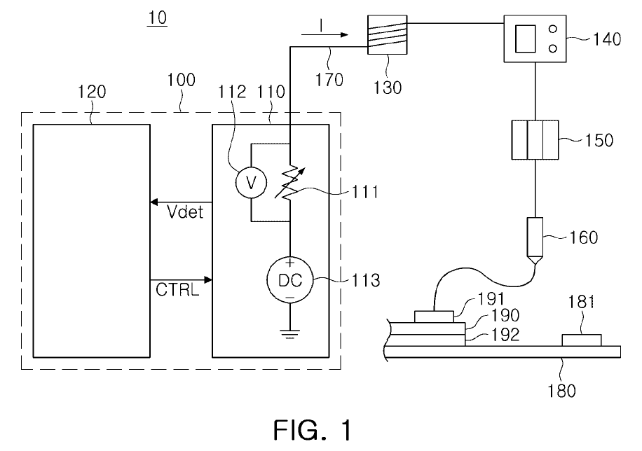

FIG. 1 is a block diagram illustrating a wire bonding device according to some implementations of the present disclosure.

Referring to FIG. 1, a wire bonding device 10 according to some implementations of the present disclosure may be a device performing a wire bonding operation to connect a bonding pad 191 of a semiconductor chip 190 to a connection pad 181 of a package substrate 180 with a wire 170. The semiconductor chip 190 may be mounted on the package substrate 180 via an adhesive layer 192. The wire bonding device 10 may include a wire bonding unit including a capillary 160 and a semiconductor package inspection apparatus 100 detecting a defect in the wire 170.

The wire bonding unit may include a spool 130 around which a wire 170 is wound, an air guide 140 controlling a position of the wire 170, the capillary 160 performing wire bonding, and at least one clamper 150 clamping the wire 170 insertedly passing through the capillary 160. The spool 130 may supply the wound wire 170 to the capillary 160. The clamper 150 may move in one direction and may fix the wire 170 through an opening and closing motion.

The semiconductor package inspection apparatus 100 may perform a semiconductor package defect inspection while the capillary 160 moves to the connection pad 181 after the wire 170 is bonded to the bonding pad 191 of the semiconductor chip 190. The semiconductor package inspection apparatus 100 may include a voltage detector 110 electrically connected to a wire 170 and a bonding controller 120 connected to the wire bonding unit and the voltage detector 110. After the wire 170 is bonded to the bonding pad 191 of the semiconductor chip 190 by the capillary 160, the voltage detector 110, while the capillary 160 is moving to the connection pad 181, may apply a DC voltage to the wire 170 and may measure a voltage applied to the wire 170.

The bonding controller 120 may control the overall operation of the wire bonding unit and the voltage detector 110. When the voltage detector 110 measures the voltage applied to the wire 170, the bonding controller 120 may control the voltage detector 110 to apply a DC voltage to the wire and may apply a ground voltage to the bonding pad 191. For example, the bonding pad 191 may be a power pad supplying power voltage to the semiconductor chip 190.

The bonding controller 120 may determine an open defect of the wire of the semiconductor chip 190 based on the detected voltage output from the voltage detector 110 and may control the operation of the capillary 160, such as stopping the wire bonding process based on the detected voltage. For example, if the detected voltage is equal to or lower than a reference voltage, the bonding controller 120 may determine that the wire 170 is not normally connected to the bonding pad 191 and thus an open defect has occurred in the wire 170. If it is determined that an open defect has occurred in the wire, the wire bonding device 10 may stop the wire bonding process by the bonding controller 120. If it is determined that the wire bonding is normally performed, the wire bonding device 10 may continue the wire bonding process.

In this manner, in a non-contact (also referred to as non-attachment) inspection method of the related art, a wire (corresponding to the wire 170 in FIG. 1) is electrically connected to a bonding pad of a semiconductor ship (corresponding to the bonding pad 191 of the semiconductor chip 190 in FIG. 1), and when a voltage is applied to the bonding pad through the wire, the voltage applied to the wire may be detected, and an open defect, such as a wire open, may be detected based on the detected voltage. However, this non-contact inspection method may only detect open defects and cannot detect short-circuit defects, such as wire shorts, cracks, pits, wire-chip touches, and electrostatic discharges (ESD). As a result, defects may only be detected at the stage of testing a package that has been completely manufactured, causing problems in that the time and cost required to make a normal semiconductor package increase and the yield and reliability of the final semiconductor package decrease.

The voltage detector 110 according to some implementations of the present disclosure may include a voltage source 113 applying a DC voltage to the wire 170, a variable resistor 111 connected between the wire 170 and the voltage source 113, and a voltmeter 112 measuring a voltage of the variable resistor 111. In addition, the bonding controller 120 may adjust the magnitude of the variable resistor 111 and the level of the DC voltage so that a wire current I flowing through the wire may be distinguished from noise. The bonding controller 120 may measure the wire current I flowing through the wire 170 based on a resistance value of the variable resistor 111 and the level of a detected voltage, and may detect a short-circuit defect of the semiconductor chip 190 based on the wire current I.

In some implementations of the present disclosure, various types of defects that may occur during the manufacturing process of the semiconductor package may be rapidly detected even before the semiconductor package is manufactured. Through this, the semiconductor package inspection apparatus 100 according to some implementations of the present disclosure may rapidly detect defects that may occur during the semiconductor package manufacturing process, thereby improving the yield and reliability of the semiconductor package.

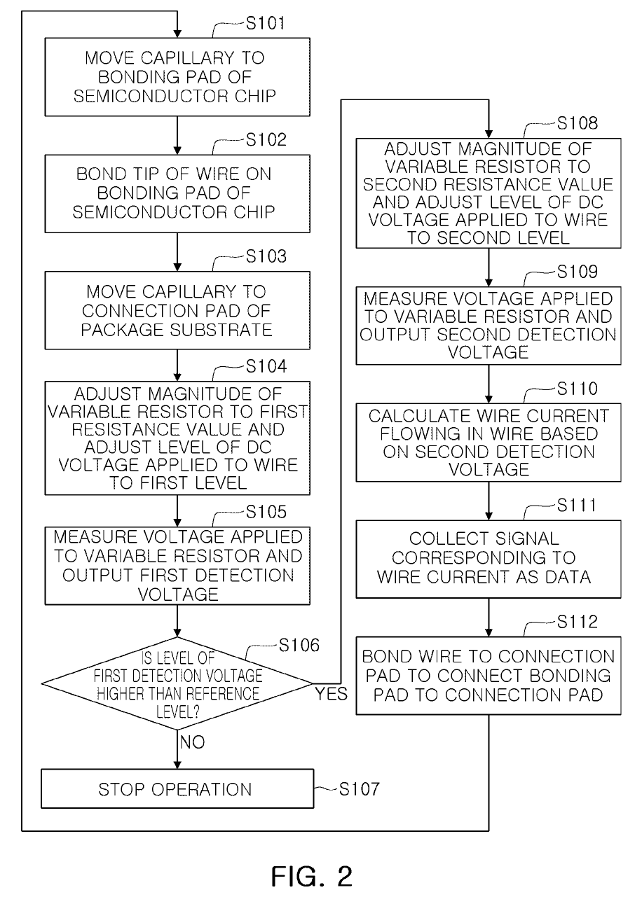

FIG. 2 is a flowchart illustrating a method of manufacturing a semiconductor package according to some implementations of the present disclosure. FIG. 2 may be a flowchart of a wire bonding process of the semiconductor package manufacturing method.

The capillary through which the wire passes may move to the bonding pad of the semiconductor chip (S101). The capillary may bond the end of the wire on the bonding pad of the semiconductor chip (S102). For example, a fire formed by a discharge torch may be pressed on the bonding pad, and the end of the wire may be bonded to the bonding pad by the fire generated by the discharge torch. The capillary may move to the connection pad of the package substrate corresponding to the bonding pad (S103).

The bonding controller may adjust the magnitude of the variable resistor connected to the wire to a first resistance value and may adjust the level of the DC voltage applied to the wire by the voltage source to a first level (S104). For example, the first resistance value may be 5 MΩ, and the first level may be 5 V. However, the magnitude of the first resistance value and the first level according to some implementations of the present disclosure are not limited thereto. The voltage detector may measure the voltage applied to the wire and output a first detected voltage to the bonding controller (S105). For example, a voltmeter included in the voltage detector may measure the voltage applied to the variable resistor having a first resistance value and output a corresponding result as the first detected voltage.

The level of the first detected voltage may be compared with a reference level (S106). If the level of the first detected voltage is lower than the reference level (NO of S106), the bonding controller may stop the wire bonding operation (S107). In this case, the bonding controller may determine that an open wire defect has occurred in the semiconductor package being wire bonded. If the level of the first detected voltage is higher than the reference level (YES of S106), the capillary may move to the connection pad to bond the wire to the connection pad, and the semiconductor package inspection apparatus may measure the wire current flowing in the wire.

The bonding controller may adjust the magnitude of the variable resistor to a second resistance value and may adjust the level of the DC voltage applied to the wire by the voltage source to the second level (S108). In some implementations, the second resistance value may be smaller than the first resistance value. For example, the second resistance value may be 100 Ω, 1 kΩ, or 10 kΩ. In some implementations, the second level may be lower than the first level. For example, the second level may be 1V. However, the magnitude of the second resistance value and the second level according to some implementations of the present disclosure are not limited thereto.

The voltage detector may measure the voltage applied to the wire and output the second detected voltage to the bonding controller (S109). For example, the voltmeter included in the voltage detector may measure the voltage applied to the variable resistor having the second resistance value and output the result as the second detected voltage. The bonding controller may measure the wire current flowing in the wire based on the level of the second resistance value and the second detected voltage (S110).

The bonding controller may collect a signal corresponding to the wire current as data (S111). In some implementations, if the magnitude of the wire current is greater than a reference current, the signal corresponding to the wire current may be determined as an abnormal signal. If the magnitude of the wire current is smaller than the reference current, the signal corresponding to the wire current may be determined as a normal signal. The signal determined as an abnormal signal or a normal signal may be collected as data.

After the wire current flowing in the wire is measured, the capillary may bond the wire to the connection pad to connect the bonding pad and the corresponding connection pad (S112). After the wire bonding is completed, the capillary may move to the next bonding pad of the semiconductor chip and perform the next wire bonding.

The semiconductor package inspection apparatus according to some implementations of the present disclosure may sequentially perform operations (S108 to S111) of detecting short-circuit defects in parallel with operations (S104 to S106) of detecting open defects of wires during the time from when the capillary bonds the wire to the bonding pad (S102) to before connecting to the connection pad corresponding to the bonding pad (S112). For example, the operations (S108 to S111) of detecting short-circuit defects may be performed after operations (S104 to S106) of detecting open defects of the wire, and the ratio of the time required for the two detection operations may be 8 to 2. However, the ratio of the time required for performing the detection operations according to some implementations of the present disclosure or the order in which they are performed is not limited thereto.

In order to inspect open defects of the wire, the voltage detector may include a resistor having a large resistance value. However, in this case, it may be difficult to measure wire current flowing in the wire. For example, when the bonding controller measures the wire current using the variable resistor having the magnitude of 5 MΩ, a current having a magnitude similar to that of noise, for example, a current having a magnitude in a μA unit, may flow through the wire. In this case, it may be difficult to measure the wire current by distinguishing it from noise.

The voltage detector according to some implementations of the present disclosure may include the variable resistor, and the bonding controller may adjust the magnitude of the variable resistor and the level of the DC voltage to distinguish the wire current from noise. That is, the bonding controller may control the voltage detector so that the magnitude of the wire current increases. For example, the bonding controller may adjust the magnitude of the variable resistor to 100 Ω and the magnitude of the DC voltage to 1 V. In this case, the wire current may have a magnitude in the mA unit, so that it may be distinguished from noise. Therefore, the semiconductor package inspection apparatus according to some implementations of the present disclosure may measure the current flowing through the wire distinguishably from noise. However, the magnitude of the variable resistor and the magnitude of the DC voltage according to some implementations of the present disclosure are not limited thereto.

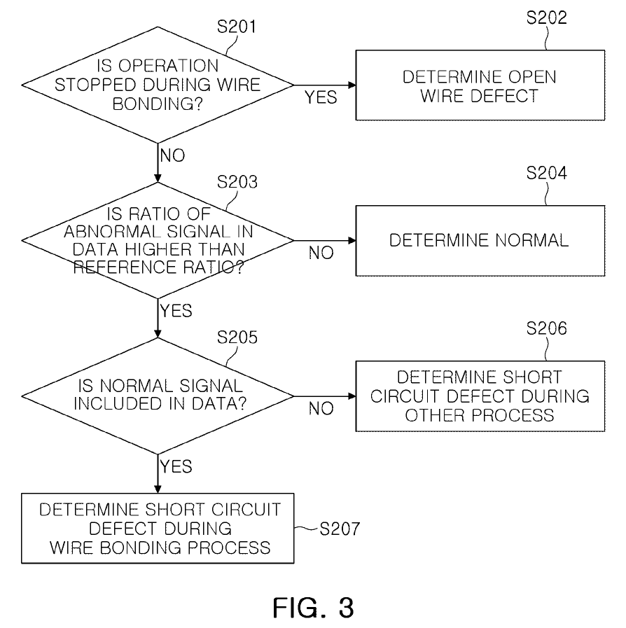

FIG. 3 is a flowchart illustrating a method of detecting a defect in a wire by the semiconductor package inspection apparatus according to some implementations of the present disclosure. In some implementations, the detection of a defect in a wire may be performed for each semiconductor chip after the wire bonding process is performed. However, the present disclosure is not limited thereto.

If the wire bonding process is stopped (YES in S201), the semiconductor package inspection apparatus may determine that a corresponding semiconductor chip has an open wire defect (S202). The wire bonding process may be performed completely without being stopped (YES in S201), but abnormal signals may be included in the data collected by the semiconductor package inspection apparatus. If the ratio of the abnormal signals in the data is lower than a reference ratio (NO in S203), the semiconductor package inspection apparatus may determine that the wire bonding process was performed normally for the semiconductor chip without a short circuit defect (S204). If the ratio of abnormal signals in the data is equal to or higher than the reference ratio (YES in S203), the semiconductor package inspection apparatus may determine that the semiconductor chip has a short circuit defect.

If the data does not include a normal signal for the semiconductor chip determined to have a short circuit defect (NO in S205), the semiconductor package inspection apparatus may determine that the semiconductor chip has a short circuit defect in a process other than the wire bonding process (S206). That is, it may be determined that the short-circuit defect of the semiconductor chip already occurred before the wire bonding process was performed. Conversely, if the data includes a normal signal (YES in S205), the semiconductor package inspection apparatus may determine that a short-circuit defect has occurred in the semiconductor chip during the wire bonding process (S207). That is, it may be determined that the short-circuit defect of the semiconductor chip has occurred during the wire bonding process.

The semiconductor package inspection apparatus according to some implementations of the present disclosure may collect a signal corresponding to the measured wire current as data and may determine in which process the short-circuit defect occurred based on the ratio of the normal signal and the abnormal signal included in the data. That is, it may be determined whether the defect detected through the semiconductor package inspection occurred during the wire bonding process or occurred in another process before the wire bonding process. Therefore, the semiconductor package inspection apparatus according to some implementations of the present disclosure may rapidly detect and rapidly resolve a defect occurring during the semiconductor package manufacturing process, thereby improving the yield and reliability of the semiconductor package.

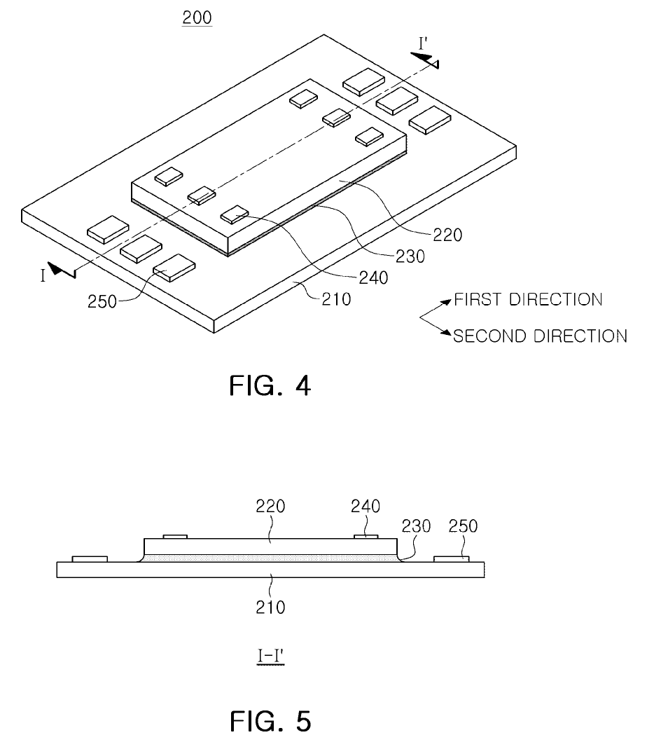

FIGS. 4 to 11 are diagrams illustrating a semiconductor package according to some implementations of the present disclosure.

FIG. 4 may be a perspective view of a semiconductor package 200 according to some implementations of the present disclosure. FIG. 5 may be a cross-sectional view illustrating a cross-section in the direction of I-I’ in FIG. 4.

Referring to FIGS. 4 and 5 together, the semiconductor package 200 according to some implementations of the present disclosure may include a package substrate 210 and a semiconductor chip 220 mounted on the package substrate 210. The semiconductor chip 220 may be mounted on the package substrate 210 via an adhesive layer 230. For example, the adhesive layer 230 may include epoxy, polyimide, or the like. A plurality of bonding pads 240 may be formed on an active surface of the semiconductor chip 220. For example, at least one of the bonding pads 240 may be a power pad for the semiconductor chip 220 to receive power voltage. On the active surface of the package substrate 210, connection pads 250 respectively corresponding to the bonding pads 240 may be formed.

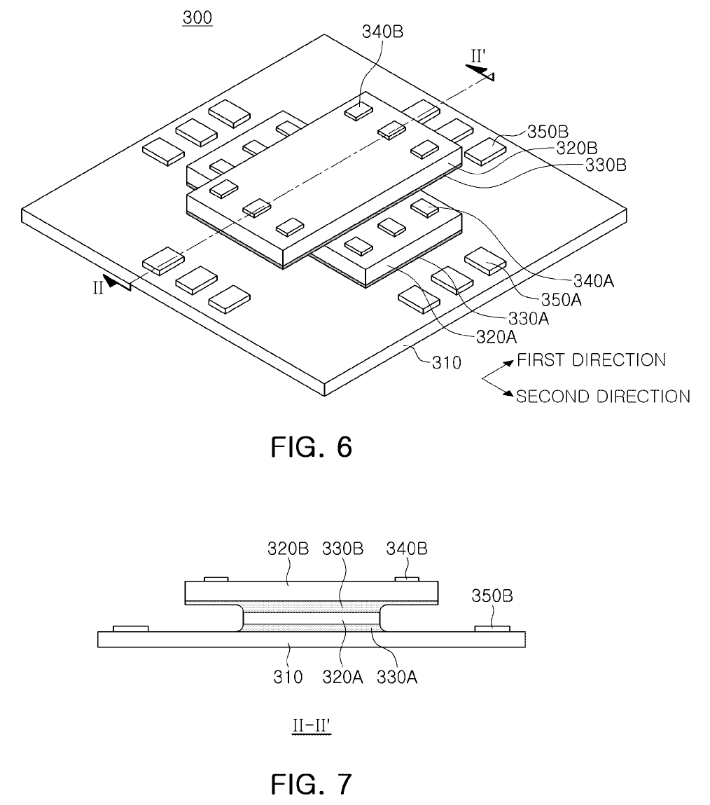

FIG. 6 may be a perspective view of a semiconductor package 300 according to some implementations of the present disclosure. FIG. 7 may be a cross-sectional view illustrating a cross-section in the direction of II-II’ in FIG. 6.

Referring to FIGS. 6 and 7 together, the semiconductor package 300 according to some implementations of the present disclosure may include a package substrate 310 and a plurality of semiconductor chips 320A and 320B mounted on the package substrate 310. The first semiconductor chip 320A may be mounted on the package substrate 310 in a first direction via an adhesive layer 330A. The second semiconductor chip 320B may be mounted on the first semiconductor chip 320A in a second direction, different from the first direction, via an adhesive layer 330B. A plurality of bonding pads 340A and 340B may be formed on active surfaces of the plurality of semiconductor chips 320A and 320B. Connection pads 350A and 350B respectively corresponding to the plurality of bonding pads 340A and 340B may be formed on the active surface of the package substrate 310.

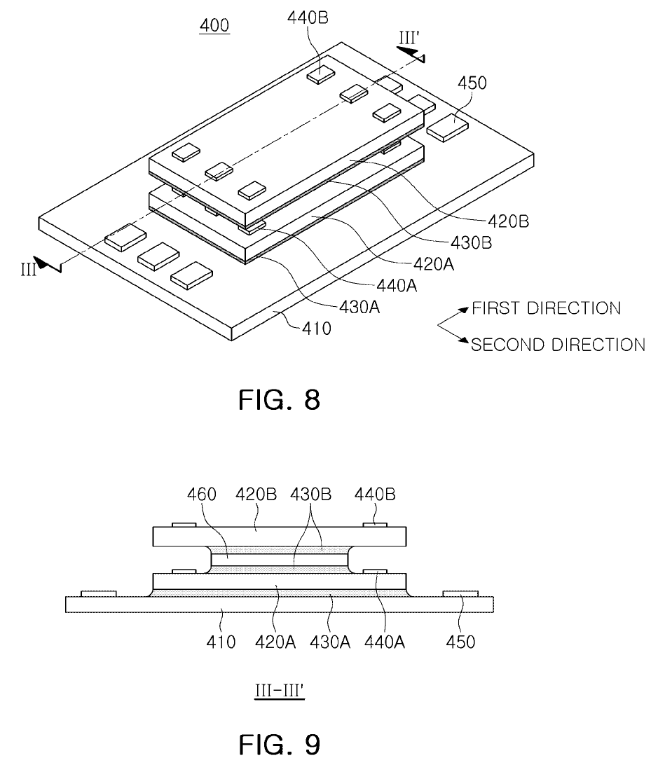

FIG. 8 may be a perspective view of a semiconductor package 400 according to some implementations of the present disclosure. FIG. 9 may be a cross-sectional view illustrating a cross-section in the direction of III-III’ of FIG. 8.

Referring to FIGS. 8 and 9 together, a package substrate 410, a plurality of semiconductor chips 420A and 420B, adhesive layers 430A and 430B, bonding pads 440A and 440B, and connection pads 450 of the semiconductor package 400 according to some implementations of the present disclosure may be similar to those of the semiconductor package 300 described above with reference to FIGS. 6 and 7 together. However, in the semiconductor package 400 described with reference to FIGS. 8 and 9 together, the plurality of semiconductor chips 420A and 420B may be mounted to face in the same direction (for example, the first direction). According to some implementations, the semiconductor package 400 may further include a spacer 460 forming a gap between the plurality of semiconductor chips 420A and 420B.

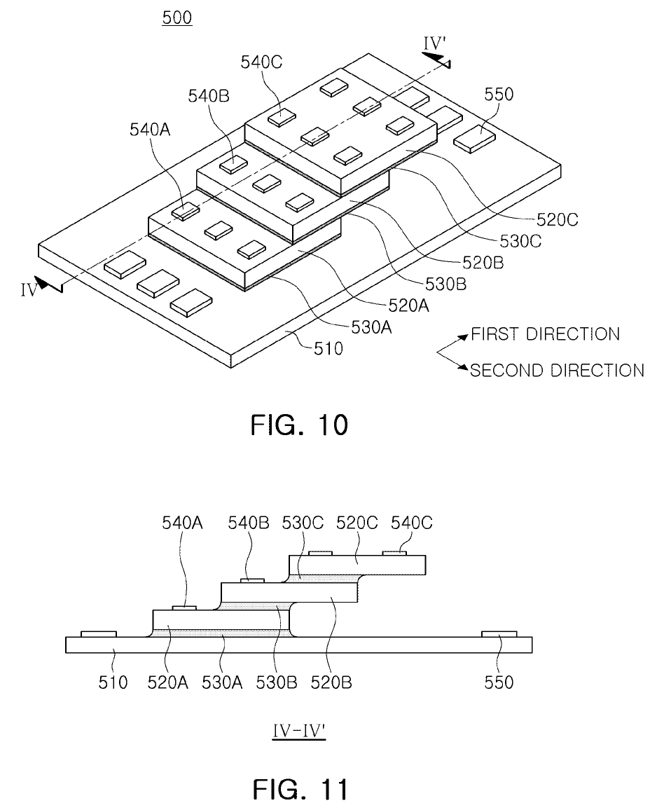

FIG. 10 may be a perspective view of a semiconductor package 500 according to some implementations of the present disclosure. FIG. 11 may be a cross-sectional view illustrating a cross-section in the direction of IV-IV’ of FIG. 10.

Referring to FIGS. 10 and 11 together, a package substrate 510, a plurality of semiconductor chips 520A, 520B, and 520C, adhesive layers 530A, 530B, and 530C, bonding pads 540A, 540B, and 540C, and connection pads 550 of the semiconductor package 500 according to some implementations of the present disclosure may be similar to those of the semiconductor package 300 described above with reference to FIGS. 6 and 7 together. However, the semiconductor package 500 described with reference to FIGS. 10 and 11 together may be mounted in a stepwise manner in which the plurality of semiconductor chips 520A, 520B, and 520C are arranged in the same direction (for example, the first direction).

As the integration density increases, in order to arrange semiconductor chips by utilizing space efficiently, some of the plurality of semiconductor chips stacked on a single package substrate may be mounted in a structure in which one end is not supported. That is, like the semiconductor packages 300, 400, and 500 of FIGS. 6 to 11, some of the plurality of semiconductor chips according to some implementations may be mounted in an overhang structure in which one end is not supported. In this case, a region in which the end is not supported in the semiconductor chip mounted in the overhang structure may have a weaker strength than that of other regions. That is, short-circuit defects, such as cracks, may easily occur in the corresponding region during the semiconductor packaging process, as compared to other regions. Wire bonding equipment including existing semiconductor package inspection apparatuses may not be able to detect such short-circuit defects.

In some implementations of the present disclosure, various types of defects that may occur during the manufacturing process of a semiconductor package may be rapidly detected even before the semiconductor package is manufactured. Through this, the semiconductor package inspection apparatus according to some implementations of the present disclosure may rapidly detect defects occurring during the semiconductor package manufacturing process, thereby improving the yield and reliability of the semiconductor package.

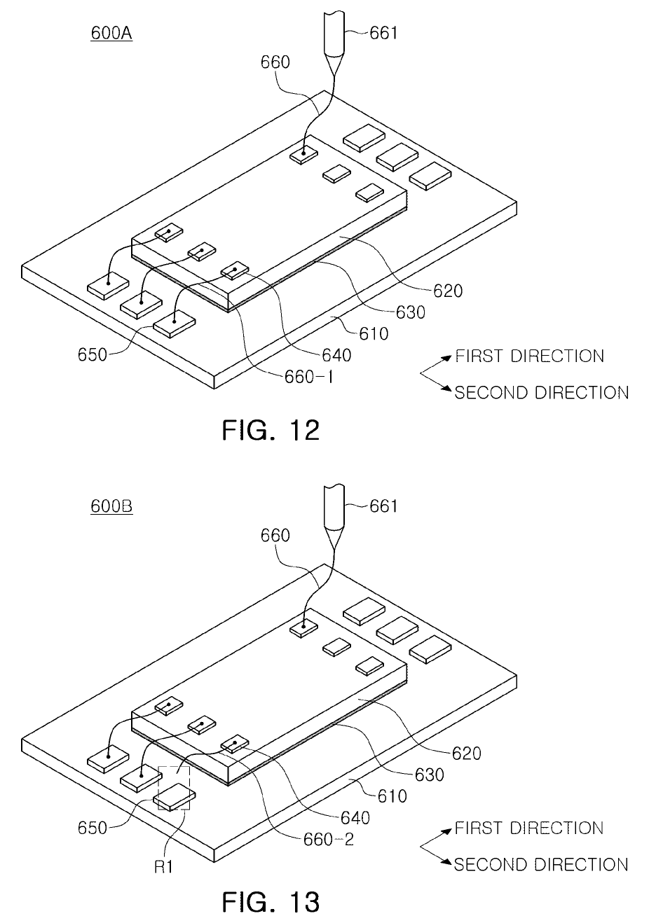

FIGS. 12 to 15 are diagrams illustrating a semiconductor package according to some implementations of the present disclosure. The semiconductor packages 600A, 600B, 600C, and 600D described with reference to FIGS. 12 to 15 is described based on the assumption of a case in which the semiconductor packages 600A, 600B, 600C, and 600D include a single semiconductor chip 220 like the semiconductor package 200 described above with reference to FIGS. 4 and 5 above, but the structure of the semiconductor package according to some implementations of the present disclosure is not limited thereto. For example, the semiconductor package according to some implementations of the present disclosure may include a plurality of semiconductor chips like the semiconductor package 300, 400, and 500 described above with reference to FIGS. 6 to 11 or may be a case in which at least one semiconductor chip is mounted in an overhang structure.

The semiconductor package 600A described with reference to FIG. 12 may be in a state in which a bonded wire 660-1 is formed normally without defects in the wire bonding process. Referring to FIG. 12, in the semiconductor package 600A according to some implementations of the present disclosure, bonding pads 640 of a semiconductor chip 620 may be electrically connected to connection pads 650 corresponding to the bonding pads 64 by the bonded wires 660-1, respectively. These bonded wires 660-1 may be formed by the wire bonding process. During the wire bonding process, a semiconductor package defect inspection may be performed through the wire 660 bonded to the bonding pad.

The semiconductor package 600B described with reference to FIG. 13 may be in an open state (region R1) because a bonded wire 660-2 is not normally connected to the connection pads 650 during the wire bonding process, unlike the semiconductor package 600A described above with reference to FIG. 12.

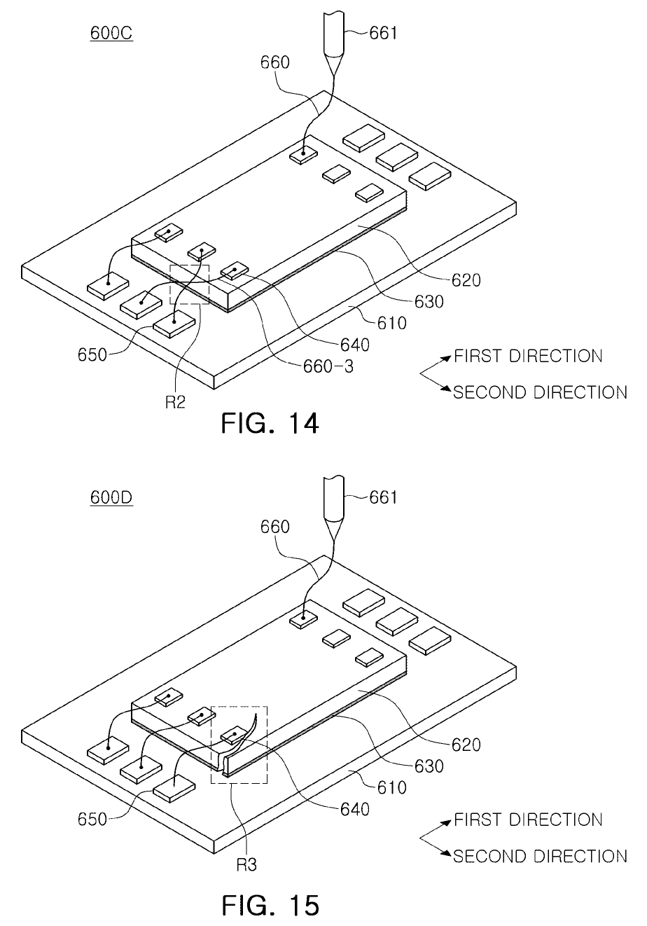

The semiconductor package 600C described with reference to FIG. 14 may be in a short-circuited state (region R2) because a bonded wires 660-3 is in contact with an adjacent bonded wire 660-3 during the wire bonding process, unlike the semiconductor package 600A described above with reference to FIG. 12.

The semiconductor package 600D described with reference to FIG. 15 may be in a state (region R3) in which a crack has occurred in a portion of the semiconductor chip 620, unlike the semiconductor package 600A described above with reference to FIG. 12. For example, the crack may refer to a defect, such as a crack, in a partial component of the semiconductor chip. Short-circuit defects, such as cracks, may occur during the wire bonding process or may occur before the wire bonding process.

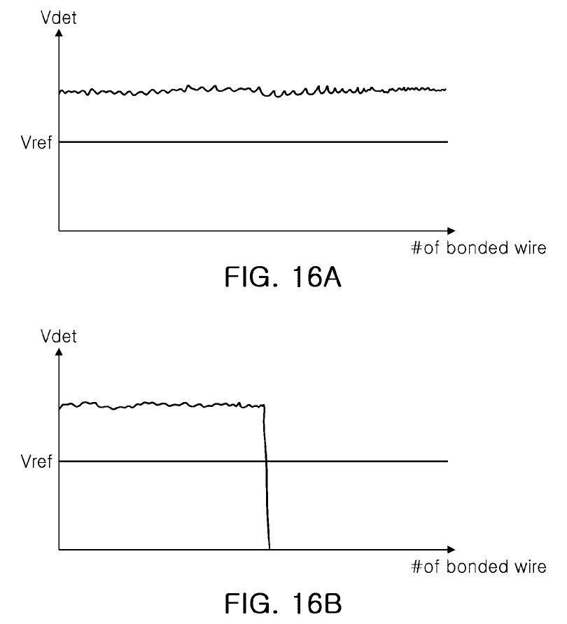

FIGS. 16A and 16B are graphs illustrating detected voltages measured by the semiconductor package inspection apparatus according to some implementations of the present disclosure. FIGS. 16A and 16B may be cases in which the bonding controller adjusts the magnitude of the variable resistor to a first resistance value and adjusts the magnitude of the DC voltage applied by the voltage source to a first level in order to detect an open defect in the wire.

FIG. 16A may be a graph illustrating a voltage detected by the voltage detector when an open defect does not occur in the wire bonding process. That is, it may be a graph illustrating a detected voltage Vdet for the semiconductor package 600A described above with reference to FIG. 12. In this case, the voltage detector may detect a voltage having a level similar to that of the DC voltage applied through the voltage source. For example, the detected voltage Vdet measured by the voltage detector may have a level higher than that of the reference voltage Vref.

FIG. 16B may be a graph illustrating a voltage detected by the voltage detector when an open defect occurs in the wire bonding process. That is, it may be a graph illustrating the detected voltage Vdet for the semiconductor package 600B described above with reference to FIG. 13. In this case, the voltage detector may detect a voltage having a level much lower than that of the DC voltage applied through the voltage source from the time when the open defect of the wire occurs. For example, the voltage detector may detect a voltage having a level lower than that of the reference voltage Vref from the time when the open defect of the wire occurs.

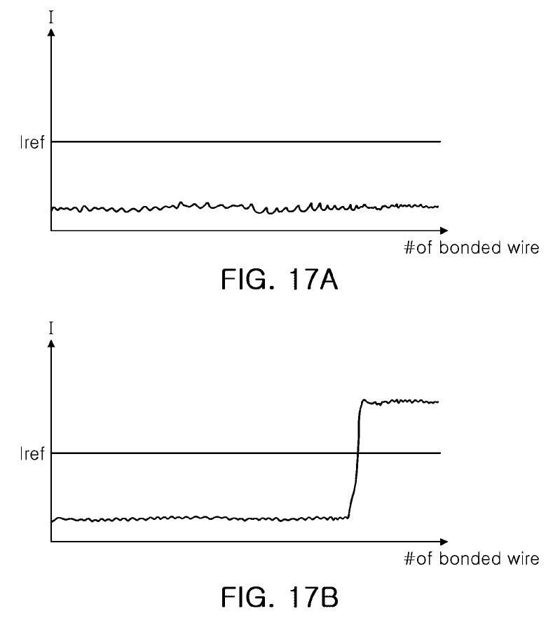

FIGS. 17A and 17B are graphs illustrating wire currents measured by the semiconductor package inspection apparatus according to some implementations of the present disclosure.

FIGS. 17A and 17B may be graphs illustrating cases in which a short circuit defect is detected for a semiconductor chip in which an open defect of the wire is not detected as described above with reference to FIG. 16A. In some implementations, the bonding controller may adjust the magnitude of the variable resistor to a second resistance value, smaller than the first resistance value, in order to detect a short-circuit defect and may adjust the magnitude of the DC voltage applied by the voltage source to the second level lower than the first level.

FIG. 17A may be a graph illustrating a wire current I measured for a semiconductor package in which a short-circuit defect has not occurred. That is, it may be a graph illustrating the wire current I for the semiconductor package 600A described above with reference to FIG. 12. Referring to FIG. 17A, the semiconductor package inspection apparatus may detect the wire current I having a value smaller than that of a reference current Iref.

FIG. 17B may be a graph illustrating the wire current I measured for a semiconductor package in which a short-circuit defect has occurred. That is, it may be a graph illustrating the wire current I for the semiconductor packages 600C and 600D described above with reference to FIGS. 14 and 15. Referring to FIG. 17B, the semiconductor package inspection apparatus may detect the wire current I having a value smaller than that of the reference current Iref, and from the time when a short-circuit defect occurs, the semiconductor package inspection apparatus may detect the wire current I having a value greater than that of the reference current Iref.

In this manner, even a semiconductor chip determined to be normal by the non-contact inspection method of the related art capable of detecting only open defects in the wire may include a short-circuit defect. As a result, there may be a problem that the defects in the package that has been completely manufactured may be detected only at the stage of testing, thereby increasing the time and cost required to manufacture a normal semiconductor package and lowering the yield and reliability of the final semiconductor package.

The semiconductor package inspection apparatus according to some implementations of the present disclosure may include the variable resistor and may measure the wire current flowing in the wire distinguishably from noise by adjusting the magnitude of the variable resistor and the level of the DC voltage. In other words, the semiconductor package inspection apparatus according to some implementations of the present disclosure may perform a short-circuit defect inspection along with an open wire defect inspection.

In this manner, in some implementations of the present disclosure, various types of defects that may occur during the manufacturing process of a semiconductor package may be rapidly detected even before the semiconductor package manufacturing process is completed. Through this, the semiconductor package inspection apparatus according to some implementations of the present disclosure may rapidly detect defects that occur during the semiconductor package manufacturing process, thereby improving the yield and reliability of the semiconductor package.

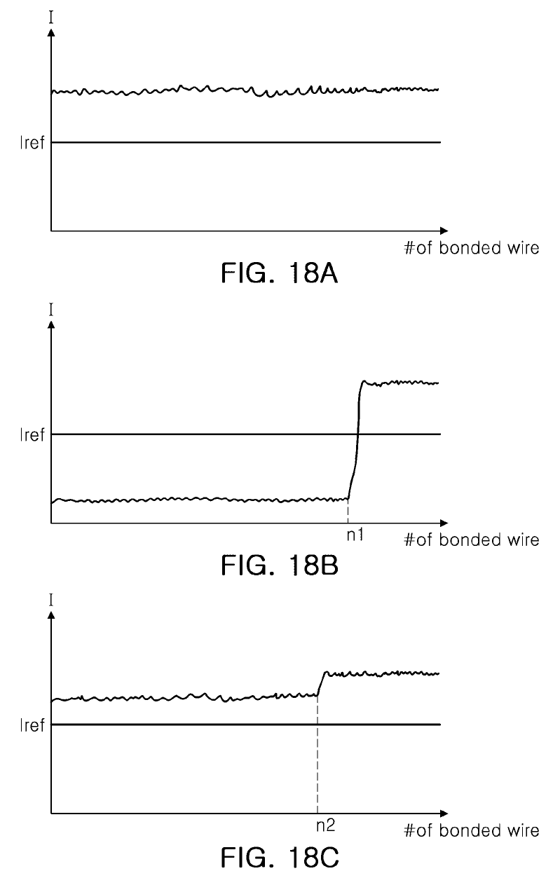

FIGS. 18A, 18B, and 18C are graphs illustrating wire currents measured by the semiconductor package inspection apparatus according to some implementations of the present disclosure.

FIG. 18A may be a graph for a case in which a short circuit defect occurs before the wire bonding process. Referring to FIG. 18A, the semiconductor package inspection apparatus may measure a wire current having a value greater than that of the reference current Iref from the time of the first measurement. In this case, the data collected by the semiconductor package inspection apparatus may include only abnormal signals.

FIG. 18B may be a graph for a case in which a short circuit defect occurs during the wire bonding process. Referring to FIG. 18B, the semiconductor package inspection apparatus may detect a wire current having a value smaller than that of the reference current Iref, and from a time point n1 when a short-circuit defect occurs, the semiconductor package inspection apparatus may detect a wire current having a value greater than that of the reference current Iref. In this case, the data collected by the semiconductor package inspection apparatus may include both a normal signal and an abnormal signal.

FIG. 18C may be a graph for a case in which a short-circuit defect occurs before the wire bonding process and an additional short-circuit defect occurs during the wire bonding process. Referring to FIG. 18C, the semiconductor package inspection apparatus may measure a wire current having a value greater than that of the reference current Iref from the time of the first measurement. In addition, the magnitude of the wire current may increase from a time point n2 when an additional short-circuit defect occurs. In this case, the data collected by the semiconductor package inspection apparatus may include only an abnormal signal.

The semiconductor package inspection apparatus according to some implementations of the present disclosure may collect a signal corresponding to the measured wire current as data and may determine in which process a short-circuit defect occurred based on the ratio of normal and abnormal signals included in the data. In other words, the semiconductor package inspection apparatus may determine whether a defect detected through semiconductor package inspection has occurred during the wire bonding process or has occurred in another process before the wire bonding process. Therefore, the semiconductor package inspection apparatus according to some implementations of the present disclosure may rapidly detect and rapidly resolve a defect occurring during the semiconductor package manufacturing process, thereby improving the yield and reliability of the semiconductor package.

According to some implementations of the present disclosure, the wire current flowing through the bonded wire may be measured distinguishably from noise using the variable resistor connected to the wire during the wire bonding process, and various defects that may occur during or before the wire bonding process may be detected based on the wire current. Therefore, a defect occurring during a semiconductor packaging process may be rapidly detected, thereby improving the yield and reliability of the semiconductor package.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While implementations have been illustrated and described above, it will be apparent to those skilled in the art that modifications and variations could be made without departing from the scope of the present disclosure as defined by the appended claims.

What is claimed is:

1. A semiconductor package inspection apparatus comprising:
a voltage detector configured to output a detected voltage measured on a wire, the wire being electrically connected to a bonding pad of at least one semiconductor chip mounted on a package substrate; and
a bonding controller configured to control the voltage detector,
wherein the voltage detector includes:
a voltage source configured to apply a DC voltage to the wire;
a variable resistor connected between the wire and the voltage source; and
a voltmeter configured to measure a voltage of the variable resistor, and
wherein the bonding controller is configured to adjust a resistance value of the variable resistor and a level of the DC voltage, measure a wire current flowing through the wire based on the resistance value of the variable resistor and the level of the detected voltage, and detect a short-circuit defect based on the wire current.

2. The semiconductor package inspection apparatus of claim 1, wherein the bonding controller is configured to:
adjust a magnitude of the variable resistor to a first resistance value, adjust the level of the DC voltage of the voltage source to a first level,
determine a signal corresponding to the wire current as an abnormal signal based on the magnitude of the wire current being greater than a reference current,
determine the signal corresponding to the wire current as a normal signal based on the magnitude of the wire current being smaller than the reference current, and
detect the short-circuit defect based on a ratio of the abnormal signal in data collected from the signal corresponding to the wire current.

3. The semiconductor package inspection apparatus of claim 2, wherein the bonding controller is configured to:
based on the data including only the abnormal signal, determine that the short-circuit defect has occurred in a process other than a wire bonding process,
based on the data including both the normal signal and the abnormal signal and the ratio of the abnormal signal is higher than a reference ratio, determine that the short-circuit defect has occurred during the wire bonding process, and
based on the ratio of the abnormal signal in the data being lower than the reference ratio, determine that the short-circuit defect has not occurred.

4. The semiconductor package inspection apparatus of claim 2, wherein the bonding controller is configured to adjust the magnitude of the variable resistor to a second resistance value that is greater than the first resistance value, adjust the level of the DC voltage to a second level, and detect an open defect in the semiconductor chip based on the level of the detected voltage.

5. The semiconductor package inspection apparatus of claim 4, wherein the second level is greater than the first level.

6. The semiconductor package inspection apparatus of claim 1, wherein the semiconductor chip includes a first semiconductor chip and a second semiconductor chip stacked on the first semiconductor chip in an overhang structure.

7. The semiconductor package inspection apparatus of claim 1, wherein the bonding pad includes a power pad, wherein the semiconductor chip is configured to receive power voltage from the power pad, and wherein the bonding controller is configured to apply a ground voltage to the bonding pad while the voltage detector measures a voltage of the wire.

8. A method of manufacturing a semiconductor package, the method comprising:
bonding an end of a wire passing through a capillary to a bonding pad of at least one semiconductor chip mounted on a package substrate;
moving the capillary to a connection pad of the package substrate corresponding to the bonding pad;
while moving the capillary to the connection pad, adjusting a magnitude of a variable resistor electrically connected to the wire to a first resistance value, adjusting a level of a DC voltage applied to the wire to a first level, and outputting a first detected voltage by measuring a voltage of the wire;
measuring a wire current flowing in the wire based on the first resistance value and a level of the first detected voltage;
detecting a short-circuit defect of the at least one semiconductor chip based on the wire current; and
bonding the wire to the connection pad to connect the bonding pad to the connection pad.

9. The method of claim 8, comprising:
collecting data that comprises a signal corresponding to the wire current,
wherein collecting data that comprises the signal corresponding to the wire current includes:
determining the signal corresponding to the wire current as an abnormal signal based on a magnitude of the wire current being greater than a reference current;
determining the signal corresponding to the wire current as a normal signal based on the magnitude of the wire current being smaller than the reference current; and
collecting data that comprises the signal determined as the abnormal signal or the normal signal.

10. The method of claim 9, wherein detecting the short-circuit defect of the at least one semiconductor chip includes:
determining that the short-circuit defect has occurred in a process other than a wire bonding process based on the data including only the abnormal signal,
determining that the short-circuit defect has occurred during the wire bonding process based on the data including both the normal signal and the abnormal signal and a ratio of the abnormal signal is higher than a reference ratio, and
determining that the short-circuit defect has not occurred based on the ratio of the abnormal signal in the data being lower than the reference ratio.

11. The method of claim 8, comprising:
adjusting the magnitude of the variable resistor to a second resistance value greater than the first resistance value,
adjusting the level of the DC voltage to a second level, and
detecting an open defect in the semiconductor chip based on a level of the second detected voltage obtained by measuring the voltage of the wire.

12. The method of claim 11, wherein the second level is greater than the first level.

13. The method of claim 8, wherein the bonding pad includes a power pad, wherein the at least one semiconductor chip is configured to receive power voltage from the power pad, and wherein the bonding controller is configured to apply a ground voltage to the bonding pad while the voltage of the wire is measured.

14. The method of claim 8, wherein the semiconductor chip includes a first semiconductor chip and a second semiconductor chip stacked in an overhang structure on the first semiconductor chip.

15. A method of manufacturing a semiconductor package, the method comprising:
bonding an end of a wire passing through a capillary to a bonding pad of at least one semiconductor chip mounted on a package substrate;
moving the capillary to a connection pad of the package substrate corresponding to the bonding pad;
measuring a wire current flowing in the wire;
bonding the wire to the connection pad to connect the bonding pad to the connection pad;
determining a signal corresponding to the wire current to be an abnormal signal based on a magnitude of the wire current being greater than a reference current, and determining a signal corresponding to the wire current to be a normal signal based on the magnitude of the wire current being smaller than the reference current;
collecting data that comprises the signal corresponding to the wire current; and
determining that the short-circuit defect has occurred in a process other than a wire bonding process based on the data including only the abnormal signal, determining that the short-circuit defect has occurred during the wire bonding process based on the data including both the normal signal and the abnormal signal and a ratio of the abnormal signal being higher than a reference ratio, and determining that the short-circuit defect has not occurred based on the ratio of the abnormal signal in the data being lower than the reference ratio.

16. The method of claim 15, wherein the bonding pad includes a power pad, wherein the semiconductor chip is configured to receive power voltage from the power pad, and wherein the bonding controller is configured to apply a ground voltage to the bonding pad while a voltage of the wire is measured.

17. The method of claim 15, comprising:
outputting a detected voltage by measuring a voltage of the wire; and
detecting an open defect based on a level of the detected voltage.

18. The method of claim 17, wherein connecting the bonding pad to the connection pad includes bonding the wire to the connection pad according to a detection result of the open defect.

19. The method of claim 17, wherein the bonding pad includes a power pad, wherein the semiconductor chip is configured to receive power voltage from the power pad, and wherein the bonding controller is configured to apply a ground voltage to the bonding pad while a voltage of the wire is measured.

20. The method of claim 15, wherein the at least one semiconductor chip includes a first semiconductor chip and a second semiconductor chip stacked on the first semiconductor chip in an overhang structure.
